(19) United States
(12) Patent Application Publication
(10) Pub. No.: US 2020/0203067 A1
(43) Pub. Date: Jun. 25, 2020

(54) MAGNETIC CORE/SHELL PARTICLES FOR INDUCTOR ARRAYS

(71) Applicant: Intel Corporation, Santa Clara, CA (US)

(72) Inventors: Malavarayan Sankarasubramanian, Chandler, AZ (US); Yongki Min, Phoenix, AZ (US); Ashay Dani, Chandler, AZ (US)

(73) Assignee: Intel Corporation, Santa Clara, CA (US)

(21) Appl. No.: 16/642,806

(22) PCT Filed: Sep. 29, 2017
(86) PCT No.: PCT/US17/54554

§ 371 Date: Feb. 27, 2020

(51) Int. Cl. H01F 41/02; H01F 1/26; H01F 27/28; H01F 27/255; H01L 49/02

(52) U.S. Cl. CPC H01F 41/0246; H01F 1/26; H01F 27/2804; H01F 2027/2819; H01L 28/10; H01F 2027/2809; H01F 27/255

(57) ABSTRACT

The inductor includes a plurality of inductive elements that are at least partially encapsulated, covered, or embedded in a composite magnetic material that improves the inductance of the inductor without a corresponding, detrimental, increase in the size of the inductor. The composite magnetic material includes a plurality of magnetic particles dispersed in a carrier medium. Each of the magnetic particles includes a magnetic core that is encapsulated in a dielectric magnetic coating. The dielectric magnetic coating is a thermally stable material having high electrical resistivity.

### TECHNICAL FIELD

The present disclosure relates to technologies associated with integrated circuit inductors.

### BACKGROUND

Electronic devices include passive electrical devices such as capacitors and inductors that are fabricated at the package core and build-up layers. For example, multiple metal layers may be deposited during a substrate manufacturing process to form an air-core inductor (ACI). As the die core area scales by generation, such scaled ACIs are unable to provide sufficient performance. This is particularly true for on package fully-integrated voltage regulators (FIVRs) where a low loss inductor is key for component for such integrated voltage regulators. Such FIVRs find extensive use in controlling and regulating the voltage output of a portable device power supply.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIG. 1 is a schematic depicting an illustrative composite magnetic material that includes a plurality of magnetic particles suspended in a carrier medium, in accordance with at least one embodiment described herein;

FIG. 2 is a plan view of an illustrative system that includes a number of inductors disposed in, on, across, or about a substrate, in accordance with at least one embodiment described herein;

FIG. 3 is a block diagram of an illustrative processor-based device equipped with at least one inductor that includes one or more inductive elements that are partially or completely embedded or encapsulated in a composite magnetic material that includes a plurality of magnetic particles carried in a carrier medium, in accordance with at least one embodiment described herein; and

FIG. 4 is a high-level logic flow diagram of an illustrative method for fabricating an inductor that includes one or more inductive elements at least partially embedded or encapsulated in a composite magnetic material that includes magnetic particles, each having a magnetic core encapsulated by a dielectric magnetic coating, in accordance with at least one embodiment described herein.

Although the following Detailed Description will proceed with reference being made to illustrative embodiments, many alternatives, modifications and variations thereof will be apparent to those skilled in the art.

### DETAILED DESCRIPTION

Magnetic inductors provide a viable alternative to air-core inductors (ACIs) when used for high frequency power delivery. Magnetic inductors advantageously demonstrate relatively low losses when operating at high frequencies. Traditional magnetic inductors use inductive elements (planar coils, helical coils, etc.) at least partially embedded or encapsulated in an electrically non-conductive dielectric matrix. The inductance of such coils may be improved through the addition of magnetic materials, such as magnetic particles, to the carrier medium surrounding the inductive elements. To maintain the insulative properties of the carrier medium the magnetic particles may be coated with a dielectric material. One disadvantage of such coatings is the volume occupied by the dielectric shell on each particle is “lost” since magnetic materials cannot occupy the volume. Another disadvantage is that heat applied to the inductor during fabrication (e.g., warm compaction, high temperature annealing, etc.) and heat generated during operation may damage the carrier medium on the particles, leading to physical and electrical contact between electrically conductive magnetic particles. If a sufficient number of magnetic particles are in physical contact, eddy currents may develop within the carrier medium leading to incomplete magnetization of the magnetic particles in the carrier medium and increased core losses within the magnetic particles. If a large number of magnetic particles are in physical contact, it is conceivable that a conductive path may be formed between adjacent inductive elements and/or adjacent coils within an inductive element, shorting the inductive element and resulting in premature component and/or system failure.

The systems and methods described herein advantageously and beneficially address the identified disadvantages of an inductor encapsulant that includes dielectric coated particles suspended in a carrier medium. Instead of using a traditional dielectric coating on the magnetic particles used in the carrier medium disposed about the inductive elements, the systems and methods described herein instead disclose an electrically non-conductive carrier medium that includes magnetic particles coated with a magnetic, high-temperature resistant, electrically non-conductive material. The dielectric material may be used to embed or encapsulate inductive elements in stand-alone packages or inductive elements incorporated into larger semiconductor packages.

The use of a magnetic coating on the magnetic particles such as described in the systems and methods contained herein beneficially increases the permeability and inductive value of inductive elements over a carrier medium containing traditional, non-magnetic coated, magnetic particles. The use of a high-temperature resistant magnetic coating on the magnetic particles beneficially reduces the likelihood of damage to the coating during high-temperature fabrication processes and operational events over a carrier medium containing traditional, magnetic particles. In addition, the use of a magnetic coating on the magnetic particles such as described in the systems and method contained herein beneficially reduces core losses within the inductor, particularly when operating at high frequencies. Further, the use of a magnetic coating on the magnetic particles such as described in the systems and method contained herein beneficially increases the resistance of the insulation between adjacent inductive elements by reducing the occurrence of coating breakdown.

An inductor that includes a composite magnetic material is provided. The inductor may include: one or more inductive elements carried by a semiconductor substrate; and a composite magnetic material disposed at least partially about each of at least some of the one or more inductive elements, the composite magnetic material including: a non-magnetic, electrically non-conductive, carrier medium; and a plurality of magnetic particles dispersed in the carrier medium, each of the magnetic particles including: a magnetic core; and a dielectric magnetic coating at least partially encapsulating the magnetic core.

A composite magnetic core material is provided. The composite magnetic core material may include: a non-magnetic, electrically non-conductive, carrier medium; and a plurality of magnetic particles dispersed in the carrier medium, each of the magnetic particles including: a magnetic core; and a dielectric magnetic coating at least partially encapsulating the magnetic core.

An electronic device is provided. The electronic device may include: a printed circuit board; and an inductor including a composite magnetic material operably coupled to the printed circuit board. The inductor may include: one or more inductive elements carried by a semiconductor substrate; and a composite magnetic material disposed at least partially about each of at least some of the one or more inductive elements, the composite magnetic material including: a non-magnetic, electrically non-conductive, carrier medium; a plurality of magnetic particles dispersed in the carrier medium, each of the magnetic particles including: a magnetic core; and a dielectric magnetic coating at least partially encapsulating the magnetic core.

A method of fabricating an inductor that includes a composite magnetic material is provided. The method may include: disposing one or more inductive elements in, on, or about a semiconductor substrate; and disposing a composite magnetic material at least partially about each of at least some of the one or more inductive elements, the composite magnetic material including: a plurality of magnetic particles dispersed in the carrier medium, each of the magnetic particles including: a magnetic core; and a dielectric magnetic coating at least partially encapsulating the magnetic core.

A system for fabricating an inductor that includes a composite magnetic material is provided. The system may include: means for disposing one or more inductive elements in, on, or about a semiconductor substrate; means for disposing a composite magnetic material at least partially about each of at least some of the one or more inductive elements, the composite magnetic material including: a non-magnetic, electrically non-conductive, carrier medium; and a plurality of magnetic particles dispersed in the carrier medium, each of the magnetic particles including: a magnetic core; and a dielectric magnetic coating at least partially encapsulating the magnetic core.

As used herein the terms “top,” “bottom,” “upper,” “lower,” “lowermost,” and “uppermost” when used in relationship to one or more elements are intended to convey a relative rather than absolute physical configuration. Thus, an element described as an “upper film layer” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, the term “logically associated” when used in reference to a number of objects, systems, or elements, is intended to convey the existence of a relationship between the objects, systems, or elements such that access to one object, system, or element exposes the remaining objects, systems, or elements having a “logical association” with or to the accessed object, system, or element. An example “logical association” exists between relational databases where access to an element in a first database may provide information and/or data from one or more elements in a number of additional databases, each having an identified relationship to the accessed element. In another example, if “A” is logically associated with “B,” accessing “A” will expose or otherwise draw information and/or data from “B,” and vice-versa.

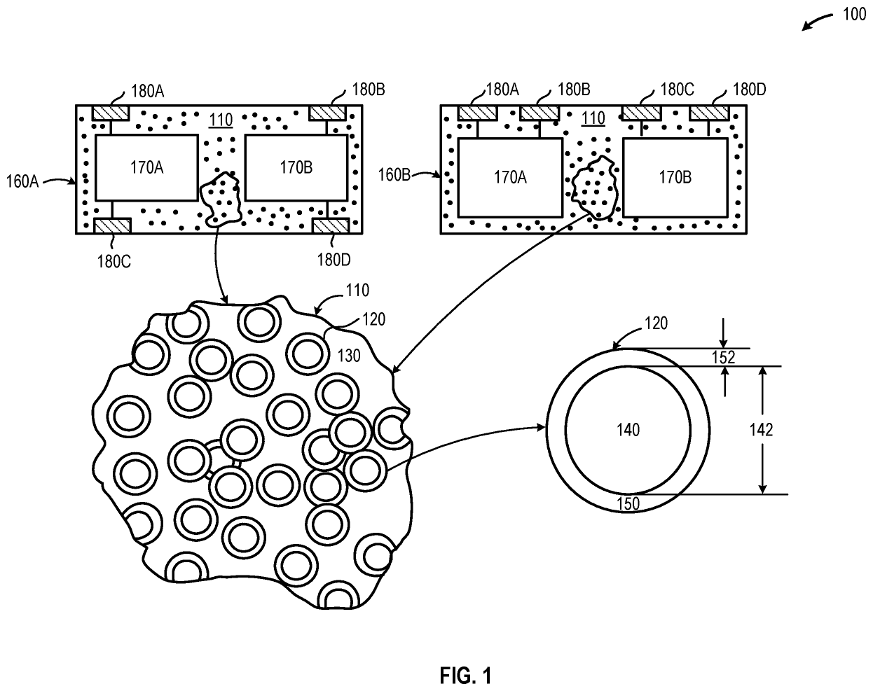

FIG. 1 is a schematic depicting an illustrative composite magnetic material 110 that includes a plurality of magnetic particles 120 suspended in a carrier medium 130, in accordance with at least one embodiment described herein. Also depicted in FIG. 1 are two illustrative inductors 160A and 160B (collectively, “inductors 160”) in which inductive elements 170A and 170B (collectively, “inductive elements 170”) are encapsulated in the composite magnetic material 110. Further depicted in FIG. 1 is a cross section of an illustrative magnetic particle 120 depicting the inner magnetic particle 140 covered by a magnetic, non-electrically conductive high-temperature coating 150 (hereinafter “magnetic coating 150”).

The composite magnetic material 110 includes magnetic particles 120 dispersed in a carrier medium 130. The composite magnetic material 110 may have a magnetic particle 120 concentration of: from about 10 volume percent (vol %) to 20 vol %; from about 20 vol % to about 25 vol %; from about 20 vol % to about 30 vol %; from about 20 vol % to about 35 vol %; from about 20 vol % to about 40 vol %; from about 20 vol % to about 45 vol %; from about 20 vol % to about 50 vol %; from about 20 vol % to about 60 vol %; from about 20 vol % to about 70 vol %; from about 20 vol % to about 80 vol %; from about 20 vol % to about 90 vol %; or from about 20 vol % to about 95 vol %. The composite magnetic material 110 may be applied, deposited, or otherwise formed in, on, about, or around the inductive elements 160 using any number and/or combination of currently available and/or future developed liquid and/or fluid application methods or processes including spray deposition, spin coating, printing, and similar.

Each of the magnetic particles 120 suspended in the composite magnetic material 110 includes a magnetic core 140 at least partially encapsulated, surrounded, or enclosed by a non-electrically conductive or dielectric magnetic coating 150. The magnetic particles 120 carried by the dielectric material may have a mean particle size distribution of: less than 0.1 micrometers (μm); less than 0.5 μm; less than 1 μm; less than 10 μm; less than 20 μm; less than 50 μm; less than 100 μm; less than 150 μm; less than 200; less than 250 μm; or less than 300 μm. The magnetic particles 120 may have a diameter of: less than 10 micrometers (μm); less than 20 μm; less than 30 μm; less than 50 μm; less than 100 μm; less than 200 μm; less than 300 μm; less than 400 μm; or less than 500 μm.

In embodiments, the carrier medium 130 may include one or more liquid or fluid dielectric materials that may be flowed about the inductive elements 170 and subsequently thermally, chemically, or photochemically cured to provide a hardened dielectric material disposed about the inductive elements 170. Example carrier medium materials may include, but are not limited to: thermosetting resins, such as epoxies; inter-penetrating polymer networks; liquid crystalline polymers (LCP); fluoropolymers, such as polytetrafluoroethylene (PTFE); and silicones. In one embodiment, the resin carrier included in the composite magnetic resin layer 112 may include bis-benzocyclobutene (BCB, for example bis-benzocyclobutene offered under the commercial name CYCLOTENE™ 3022 by Dow Chemical Co., MIDLAND, Mich.). In some embodiments, a liquid crystalline polymer may include one or more polymers or polymer mixtures heated above its glass or melting transition point (e.g., thermotropic liquid-crystal polymers). In some embodiment, the resin carrier included in the composite magnetic resin layer may include one or more epoxies such as Bisphenol A, Bisphenol F, Novolac, aliphatic, glycidylamine mixed with hardeners of type, amines, anhydrides, phenols and thiols.

The magnetic core 140 may include one or more magnetic materials and/or magnetic compounds, such as one or more metallic magnetic materials or one or more soft ferrites. Example metallic magnetic materials suitable for use as the magnetic core 140 include, but are not limited to: iron (Fe); oriented iron silicide (FeSi); unoriented iron silicide (FeSi); iron-nickel (FeNi) and iron nickel containing alloys; iron-cobalt (FeCo) and iron-cobalt containing alloys; FeSiBNbCu and FeSiBNbCu containing alloys; and CoZrTa and CoZrTa containing alloys. Example soft ferrite magnetic materials include, but are not limited to: manganese-zinc ferrite (MnZn); nickel-zinc ferrite (NiZn); and ferric oxide (Fe₂O₃). The magnetic core 140 may have a diameter 142 of: less than 0.1 micrometers (μm); less than 0.5 μm; less than 1 μm; less than 5 μm; less than 10 μm; less than 20 μm; less than 40 μm; less than 90 μm; less than 150 μm; less than 250 μm; less than 350 μm; or less than 450 μm.

The magnetic coating 150 may include one or more electrically non-conductive or dielectric coatings having magnetic properties and demonstrating thermal stability to a defined temperature to account for either or both high-temperature fabrication and/or high operational temperatures. In some implementations, the magnetic coating 150 may include one or more layers deposited on, about, or across at least a portion of the exterior surface of a magnetic core 140. In some implementations, the magnetic coating 150 may include an inorganic magnetic coating. Example inorganic magnetic coatings suitable for use as the magnetic coating 150 include, but are not limited to: one or more soft ferrites, such as manganese-zinc ferrite (MnZn); nickel-zinc ferrite (NiZn); ferric oxide (Fe₂O₃); and ferromagnetic materials having a cubic crystalline structure and the general composition MO.Fe₂O₃ where M is a transition metal, such as nickel, manganese, or zinc. The magnetic coating 150 may be applied to the magnetic core 140 using any currently available or future developed material deposition process or method. Example material deposition methods include, but are not limited to: heating stoichiometric quantities of ferrites with oxides, a sol-gel process; a spark plasma sintering process, a microwave process; or a co-precipitation process. The magnetic shell 150 may have a thickness 152 of: less than 0.1 micrometers (μm); less than 0.5 μm; less than 1 μm; less than 2 μm; less than 3 μm; less than 4 μm; less than 5 μm; less than 10 μm; less than 15 μm; less than 20 μm; or less than 25 μm. In embodiments, the magnetic coating 150 may include materials physically and/or magnetically stable at temperatures of: less than 200° F.; less than 300° F.; less than 400° F.; less than 500° F.; less than 750° F.; or less than 1000° F.

Each of the inductors 160 includes one or more inductive elements 170. The inductive elements 170 may be embedded, encapsulated, or otherwise disposed in the composite magnetic material 110. When compared to traditional, non-magnetic coated magnetic particles 120, the enhanced magnetic properties of the composite magnetic material 110 beneficially increases the permeability magnetic core of the inductive elements 170 included in the inductor 160. Further, when compared to traditional, non-magnetic coated magnetic particles 120, the enhanced magnetic properties of the composite magnetic material 110 beneficially reduce eddy current losses in the inductors 160, particularly at frequencies used for power delivery to central processing units (CPUs). In addition, the coated magnetic particles described herein prevent the formation of conductive pathways between adjacent inductive elements, increasing the insulation resistance between adjacent inductive elements. Under extreme conditions, such may prevent shorting within the inductive array. Such performance advantages also permit the use of physically smaller inductors 160 in applications such as a fully integrated voltage regulators (FIVRs).

Each of the inductors 160 may include inductive elements 170 that include conductive traces arranged to provide a planar inductive coil or helical inductive coil. In embodiments, each of the inductive elements 170 may be formed, deposited, or otherwise patterned onto layers of dielectric material forming a substrate, package, or modules. In embodiments, each of the inductive elements 170 may be formed using any conductive material, such as copper, a copper containing alloy, aluminum, an aluminum containing alloy, or similar material demonstrating low electrical resistance. Although each of the inductors 160 in FIG. 1 includes two inductive elements 170, those of ordinary skill in the art will readily appreciate that each of the inductors 160 may include any number of inductive elements 170. Each of the inductive elements 170 may be conductively coupled to a number of contact pads 180A-180D disposed on, in, about, or across a surface of the respective inductor 160.

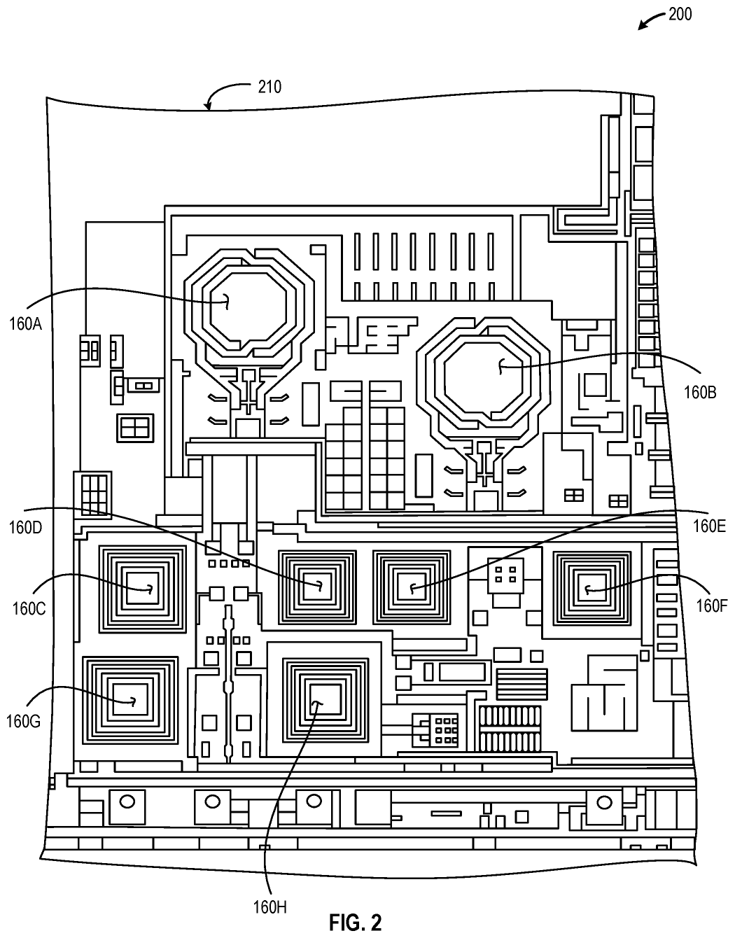

FIG. 2 is a plan view of an illustrative system 200 that includes a number of inductors 160A-160H (collectively, “inductors 160”) disposed in, on, across, or about a substrate 210, in accordance with at least one embodiment described herein. The substrate 210 may include a semiconductor substrate, a printed circuit board, or similar member to which the inductors 160 are operably coupled. Some or all of the inductors 160 depicted in FIG. 2 may include inductive elements 170 that are partially or completely embedded or encapsulated in a composite magnetic material 110 that includes a plurality of magnetic particles 120 carried in a carrier medium 130.

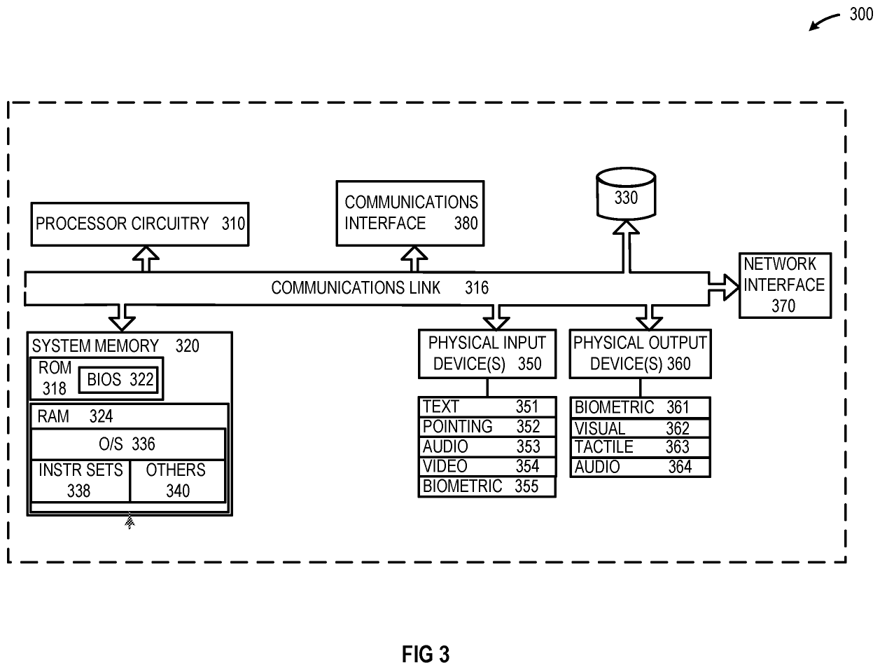

FIG. 3 is a block diagram of an illustrative processor-based device 300 equipped with at least one inductor 160 that includes one or more inductive elements 170 that are partially or completely embedded or encapsulated in a composite magnetic material 110 that includes a plurality of magnetic particles 120 carried in a carrier medium 130, in accordance with at least one embodiment described herein. The following discussion provides a brief, general description of the components forming the illustrative processor-based device 300 such as a smartphone, wearable computing device, portable computing device, or similar device that includes at least one inductor 160 that includes one or more inductive elements 170 that are partially or completely embedded or encapsulated in a composite magnetic material 110 that includes a plurality of magnetic particles 120 carried in a carrier medium 130. For example, the processor-based device may include a power supply containing one or more fully integrated voltage regulators (FIVRs) that include one or more inductors 160 such as described in FIG. 1 above.

The processor-based device 300 includes processor circuitry 310 capable of executing machine-readable instruction sets, reading data from a storage device 330 and writing data to the storage device 330. Those skilled in the relevant art will appreciate that the illustrated embodiments as well as other embodiments can be practiced with other circuit-based device configurations, including portable electronic or handheld electronic devices, for instance smartphones, portable computers, wearable computers, microprocessor-based or programmable consumer electronics, personal computers (“PCs”), network PCs, minicomputers, mainframe computers, and the like.

The processor circuitry 310 may include any number of hardwired or configurable circuits, some or all of which may include programmable and/or configurable combinations of electronic components, semiconductor devices, and/or logic elements that are disposed partially or wholly in a PC, server, or other computing system capable of executing machine-readable instructions. The processor-based device 300 includes the processor circuitry 310 and bus or similar communications link 316 that communicably couples and facilitates the exchange of information and/or data between various system components including a system memory 320, and/or one or more rotating data storage devices 330. The processor-based device 300 may be referred to in the singular herein, but this is not intended to limit the embodiments to a single device and/or system, since in certain embodiments, there will be more than one processor-based device 300 that incorporates, includes, or contains any number of communicably coupled, collocated, or remote networked circuits or devices.

The processor circuitry 310 may include any number, type, or combination of devices. At times, the processor circuitry 310 may be implemented in whole or in part in the form of semiconductor devices such as diodes, transistors, inductors, capacitors, and resistors. Such an implementation may include, but is not limited to any current or future developed single- or multi-core processor or microprocessor, such as: on or more systems on a chip (SOCs); central processing units (CPUs); digital signal processors (DSPs); graphics processing units (GPUs); application-specific integrated circuits (ASICs), field programmable gate arrays (FPGAs), and the like. Unless described otherwise, the construction and operation of the various blocks shown in FIG. 3 are of conventional design. Consequently, such blocks need not be described in further detail herein, as they will be understood by those skilled in the relevant art. The communications link 316 that interconnects at least some of the components of the processor-based device 300 may employ any known serial or parallel bus structures or architectures.

The system memory 320 may include read-only memory (“ROM”) 318 and random access memory (“RAM”) 324. A portion of the ROM 318 may be used to store or otherwise retain a basic input/output system (“BIOS”) 322. The BIOS 322 provides basic functionality to the processor-based device 300, for example by causing the processor circuitry 310 to load one or more machine-readable instruction sets. In embodiments, at least some of the one or more machine-readable instruction sets cause at least a portion of the processor circuitry 310 to provide, create, produce, transition, and/or function as a dedicated, specific, and particular machine, for example a word processing machine, a digital image acquisition machine, and similar. In some implementations all or a portion of the system memory 320 may be disposed in a common semiconductor package with the processor circuitry, such as a system-on-a- chip, or SoC.

The processor-based device 300 may include one or more communicably coupled, non-transitory, data storage devices, such as one or more hard disk drives 330. The one or more data storage devices 330 may include any current or future developed storage appliances, networks, and/or devices. Non-limiting examples of such data storage devices 330 may include, but are not limited to, any current or future developed non-transitory storage appliances or devices, such as one or more magnetic storage devices, one or more optical storage devices, one or more electro-resistive storage devices, one or more molecular storage devices, one or more quantum storage devices, or various combinations thereof. In some implementations, the one or more data storage devices 330 may include one or more removable storage devices, such as one or more flash drives, flash memories, flash storage units, or similar appliances or devices capable of communicable coupling to and decoupling from the processor-based device 300.

The one or more data storage devices 330 may include interfaces or controllers (not shown) communicatively coupling the respective storage device or system to the communications link 316. The one or more data storage devices 330 may store, retain, or otherwise contain machine-readable instruction sets, data structures, program modules, data stores, databases, logical structures, and/or other data useful to the processor circuitry 310 and/or one or more applications executed on or by the processor circuitry 310. In some instances, one or more data storage devices 330 may be communicably coupled to the processor circuitry 310, for example via communications link 316 or via one or more wired communications interfaces (e.g., Universal Serial Bus or USB); one or more wireless communications interfaces (e.g., Bluetooth®, Near Field Communication or NFC); one or more wired network interfaces (e.g., IEEE 802.3 or Ethernet); and/or one or more wireless network interfaces (e.g., IEEE 802.11 or WiFi®).

Machine-readable instruction sets 338 and other modules 340 may be stored in whole or in part in the system memory 320. Such instruction sets 338 may be transferred, in whole or in part, from the one or more data storage devices 330. The instruction sets 338 may be loaded, stored, or otherwise retained in system memory 320, in whole or in part, during execution by the processor circuitry 310. The machine-readable instruction sets 338 may include machine-readable and/or processor-readable code, instructions, or similar logic capable of providing the speech coaching functions and capabilities described herein.

A system user may provide, enter, or otherwise supply commands (e.g., selections, acknowledgements, confirmations, and similar) as well as information and/or data (e.g., subject identification information, color parameters) to the processor-based device 300 using one or more communicably coupled input devices 350. The one or more communicably coupled input devices 350 may be disposed local to or remote from the processor-based device 300. The input devices 350 may include one or more: text entry devices 351 (e.g., keyboard); pointing devices 352 (e.g., mouse, trackball, touchscreen); audio input devices 353; video input devices 354; and/or biometric input devices 355 (e.g., fingerprint scanner, facial recognition, iris print scanner, voice recognition circuitry). In embodiments, at least some of the one or more input devices 350 may include a wired or wireless interface that communicably couples the input device 350 to the processor-based device 300.

The system user may receive output from the processor-based device 300 via one or more output devices 360. In at least some implementations, the one or more output devices 360 may include, but are not limited to, one or more: biometric output devices 361; visual output or display devices 362; tactile output devices 363; audio output devices 364, or combinations thereof. In embodiments, at least some of the one or more output devices 360 may include a wired or a wireless communicable coupling to the processor-based device 300.

For convenience, a network interface 370, the processor circuitry 310, the system memory 320, the one or more input devices 350 and the one or more output devices 360 are illustrated as communicatively coupled to each other via the communications link 316, thereby providing connectivity between the above-described components. In alternative embodiments, the above-described components may be communicatively coupled in a different manner than illustrated in FIG. 3. For example, one or more of the above-described components may be directly coupled to other components, or may be coupled to each other, via one or more intermediary components (not shown). In some embodiments, all or a portion of the communications link 316 may be omitted and the components are coupled directly to each other using suitable wired or wireless connections.

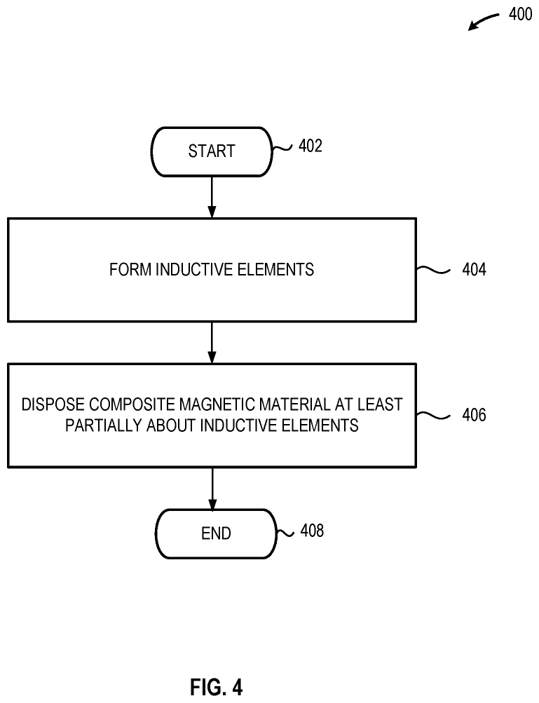

FIG. 4 is a high-level logic flow diagram of an illustrative method for fabricating an inductor 160 that includes one or more inductive elements 170 at least partially embedded or encapsulated in a composite magnetic material 110 that includes magnetic particles 120, each having a magnetic core 140 encapsulated by a dielectric magnetic coating 150, in accordance with at least one embodiment described herein. The method 400 commences at 402.

At 404, one or more inductive elements 170 are formed. In some embodiments, the inductive elements 170 may be deposited, formed, patterned or otherwise disposed in, on, across, or about a substrate material. In some implementations, the substrate may include a doped or undoped semiconductor material. In some implementations, the substrate material may include a printed circuit board. In some embodiments, the one or more inductive elements 170 may include one or more planar inductors or planar coils formed on a surface or single printed circuit board layer. In some embodiments, the one or more inductive elements 170 may include one or more helical or non-planar coils formed on multiple surfaces or multiple printed circuit board layers.

At 406, a composite magnetic material 110 is disposed at least partially about the inductive elements 170. In some implementations, at least a portion of the inductive elements 170 may remain exposed. For example, the inductive elements 170 may be embedded in the composite magnetic material 110. In some implementations, the inductive elements 170 may be encapsulated in the composite magnetic material 110. The composite magnetic material 110 may include a plurality of magnetic particles 120 dispersed or otherwise suspended in a carrier material 130. The composite magnetic material 110 may include one or more curable materials that may be flowed about the inductive elements and cured to a stable (e.g., solid) form. For example, the carrier material 120 may include one or more thermosetting polymers or chemically cured epoxy materials. Each of the magnetic particles 120 may include a magnetic core 140 covered by a dielectric magnetic coating 150. In some implementations, the dielectric magnetic coating 150 may include a material demonstrating chemical and physical stability at elevated temperatures. For example, the dielectric magnetic coating may demonstrate chemical and physical stability to temperatures of up to about 400° F. In embodiments, the dielectric magnetic coating 150 may include one or more organic or inorganic materials having an electrical resistivity (ρ) of from about 100 ohm-meter (Ωm) to about 10¹⁷ Ωm.

At 408, the lower surface 144 of the spacer die 140 is physically coupled to the upper surface 132 of the semiconductor package substrate 130. The physical coupling of the lower surface 144 of the spacer die 140 to the upper surface 132 of the semiconductor package substrate 130 may be accomplished using any currently available or future developed die attachment method or process. For example, the lower surface 144 of the spacer die 140 may be physically coupled to the upper surface 132 of the semiconductor package substrate 130 using a die attach adhesive or a die attach film. The method 400 concludes at 410.

While FIG. 4 illustrates various operations according to one or more embodiments, it is to be understood that not all of the operations depicted in FIG. 4 are necessary for other embodiments. Indeed, it is fully contemplated herein that in other embodiments of the present disclosure, the operations depicted in FIG. 4, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

Any of the operations described herein may be implemented in a system that includes one or more mediums (e.g., non-transitory storage mediums) having stored therein, individually or in combination, instructions that when executed by one or more processors perform the methods. Here, the processor may include, for example, a server CPU, a mobile device CPU, and/or other programmable circuitry. Also, it is intended that operations described herein may be distributed across a plurality of physical devices, such as processing structures at more than one different physical location. The storage medium may include any type of tangible medium, for example, any type of disk including hard disks, floppy disks, optical disks, compact disk read-only memories (CD-ROMs), rewritable compact disks (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, Solid State Disks (SSDs), embedded multimedia cards (eMMCs), secure digital input/output (SDIO) cards, magnetic or optical cards, or any type of media suitable for storing electronic instructions. Other embodiments may be implemented as software executed by a programmable control device.

Thus, the present disclosure is directed to inductors for use with semiconductors. The inductor includes a plurality of inductive elements that are at least partially encapsulated, covered, or embedded in a composite magnetic material that improves the inductance of the inductor without a corresponding, detrimental, increase in the size of the inductor. The composite magnetic material includes a plurality of magnetic particles dispersed in a carrier medium. Each of the magnetic particles includes a magnetic core that is encapsulated in a dielectric magnetic coating. The dielectric magnetic coating is a thermally stable material having high electrical resistivity.

The following examples pertain to further embodiments. The following examples of the present disclosure may comprise subject material such as at least one device, a method, at least one machine-readable medium for storing instructions that when executed cause a machine to perform acts based on the method, means for performing acts based on the method and/or a system for fabricating an inductor that includes inductive elements disposed in a composite magnetic material. The composite magnetic material includes a plurality of magnetic particles dispersed in and carried by a non-magnetic, electrically non-conductive, carrier medium. The magnetic particles may include a magnetic core surrounded by a dielectric magnetic coating.

According to example 1, there is provided an inductor that includes a composite magnetic material. The inductor may include: one or more inductive elements carried by a semiconductor substrate; and a composite magnetic material disposed at least partially about each of at least some of the one or more inductive elements, the composite magnetic material including: a non-magnetic, electrically non-conductive, carrier medium; and a plurality of magnetic particles dispersed in the carrier medium, each of the magnetic particles including: a magnetic core; and a dielectric magnetic coating at least partially encapsulating the magnetic core.

Example 2 may include elements of example 1 where the one or more inductive elements may include at least one of: a planar coil disposed on a single substrate layer or a stacked coil disposed across multiple substrate layers.

Example 3 may include elements of any of examples 1 or 2 where the semiconductor substrate may include a printed circuit board.

Example 4 may include elements of any of examples 1 through 3 where the semiconductor substrate may include a system-on-a-chip (SoC).

Example 5 may include elements of any of examples 1 through 4 where the composite magnetic material may include a carrier having a solids concentration of at least 20% by weight.

Example 6 may include elements of any of examples 1 through 5 where the magnetic core particles may include at least one of: Fe, oriented FeSi, unoriented FeSi, FeNi, FeCo, FeSiBNbCu, FeCoMoB, FeSiB, FeSiBNb, FeSiBP, or CoZrTa.

Example 7 may include elements of any of examples 1 through 6 where the dielectric magnetic coating may include a soft ferrite.

Example 8 may include elements of any of examples 1 through 7 where the dielectric magnetic coating may include at least one of: MnZn, NiZn, or Fe₂O₃.

Example 9 may include elements of any of examples 1 through 8 where the magnetic core may have a diameter of from: 0.05 micrometers (μm) to 500 μm.

Example 10 may include elements of any of examples 1 through 9 where the dielectric magnetic coating may have a thickness of from; 0.01 micrometer (μm) to 100 μm.

Example 11 may include elements of any of examples 1 through 10 where the carrier medium may include a photocurable, chemically curable, thermally curable, or electromagnetically curable material.

Example 12 may include elements of any of examples 1 through 11 where the carrier medium may include a thermosetting epoxy.

Example 13 may include elements of any of examples 1 through 12 where the one or more inductive elements may include a plurality of inductive elements; and where the composite magnetic material encapsulates at least some of the plurality of inductive elements.

According to example 14, there is provided a composite magnetic core material. The composite magnetic core material may include: a non-magnetic, electrically non-conductive, carrier medium; and a plurality of magnetic particles dispersed in the carrier medium, each of the magnetic particles including: a magnetic core; and a dielectric magnetic coating at least partially encapsulating the magnetic core.

Example 15 may include elements of example 14 where the composite magnetic material may have a solids concentration of at least 20% by weight.

Example 16 may include elements of any of examples 14 or 15 where the magnetic core comprises at least one of: Fe, oriented FeSi, unoriented FeSi, FeNi, FeCo, FeCoMoB, FeSiB, FeSiBNb, FeSiBP, FeSiBNbCu, or CoZrTa.

Example 17 may include elements of any of examples 14 through 16 where the dielectric magnetic coating may include a soft ferrite.

Example 18 may include elements of any of examples 14 through 17 where the dielectric magnetic coating may include at least one of: MnZn, NiZn, or Fe₂O₃.

Example 19 may include elements of any of examples 14 through 18 where the magnetic core has a diameter of from: 0.05 micrometers (μm) to 500 μm.

Example 20 may include elements of any of examples 14 through 19 where the dielectric magnetic coating has a thickness of from; 0.01 micrometer (μm) to 100 μm.

Example 21 may include elements of any of examples 14 through 21 where the carrier material may include a photocurable, chemically curable, thermally curable, or electromagnetically curable material.

Example 22 may include elements of any of examples 14 through 21 where the carrier material may include a thermosetting epoxy.

According to example 23, there is provided an electronic device. The electronic device may include: a printed circuit board; and an inductor including a composite magnetic material operably coupled to the printed circuit board. The inductor may include: one or more inductive elements carried by a semiconductor substrate; and a composite magnetic material disposed at least partially about each of at least some of the one or more inductive elements, the composite magnetic material including: a non-magnetic, electrically non-conductive, carrier medium; a plurality of magnetic particles dispersed in the carrier medium, each of the magnetic particles including: a magnetic core; and a dielectric magnetic coating at least partially encapsulating the magnetic core.

Example 24 may include elements of example 23 where the one or more inductive elements may include at least one of: a planar coil disposed on a single substrate layer or a stacked coil disposed across multiple substrate layers.

Example 25 may include elements of any of examples 23 or 24 where the semiconductor substrate may include a printed circuit board.

Example 26 may include elements of any of examples 23 through 25 where the semiconductor substrate may include a system-on-a-chip (SoC).

Example 27 may include elements of any of examples 23 through 26 where the composite magnetic material may include a carrier having a solids concentration of at least 20% by weight.

Example 28 may include elements of any of examples 23 through 27 where the magnetic core comprises at least one of: Fe, oriented FeSi, unoriented FeSi, FeNi, FeCo, FeSiBNbCu, FeCoMoB, FeSiB, FeSiBNb, FeSiBP, or CoZrTa.

Example 29 may include elements of any of examples 23 through 28 where the dielectric magnetic coating may include a soft ferrite.

Example 30 may include elements of any of examples 23 through 29 where the dielectric magnetic coating comprises at least one of: MnZn, NiZn, or Fe₂O₃.

Example 31 may include elements of any of examples 23 through 30 where the magnetic core has a diameter of from: 0.05 micrometers (μm) to 500 μm.

Example 32 may include elements of any of examples 23 through 31 where the dielectric magnetic coating has a thickness of from; 0.01 micrometers (μm) to 1 μm.

Example 33 may include elements of any of examples 23 through 32 where the carrier medium may include a chemically, thermally, or electromagnetically curable material.

Example 34 may include elements of any of examples 23 through 33 where the carrier medium may include a thermosetting epoxy.

Example 35 may include elements of any of examples 23 through 34 where the one or more inductive elements may include a plurality of inductive elements; and where the composite magnetic material encapsulates at least some of the plurality of inductive elements.

According to example 36, there is provided a method of fabricating an inductor that includes a composite magnetic material. The method may include: disposing one or more inductive elements in, on, or about a semiconductor substrate; and disposing a composite magnetic material at least partially about each of at least some of the one or more inductive elements, the composite magnetic material including: a plurality of magnetic particles dispersed in the carrier medium, each of the magnetic particles including: a magnetic core; and a dielectric magnetic coating at least partially encapsulating the magnetic core.

Example 37 may include elements of example 36 where disposing one or more inductive elements in, on, or about a semiconductor substrate may include: disposing, in, on, or about a semiconductor substrate, one or more inductive elements that include at least one of: a planar coil disposed on a single substrate layer or a stacked coil disposed across multiple substrate layers.

Example 38 may include elements of any of examples 36 or 37 where disposing one or more inductive elements in, on, or about a semiconductor substrate may include: disposing one or more inductive elements in, on, or about a printed circuit board.

Example 39 may include elements of any of examples 36 through 38 where disposing one or more inductive elements in, on, or about a semiconductor substrate may include: disposing one or more inductive elements in, on, or about a system-on-a-chip (SoC).

Example 40 may include elements of any of examples 36 through 39 where disposing a composite magnetic material at least partially about each of at least some of the one or more inductive elements may include: disposing a composite magnetic material having a solids concentration of at least 40% by weight at least partially about each of at least some of the one or more inductive elements.

Example 41 may include elements of any of examples 36 through 40 where disposing a composite magnetic material at least partially about each of at least some of the one or more inductive elements may include: disposing a composite magnetic material at least partially about each of at least some of the one or more inductive elements, the composite magnetic material including magnetic particles that include magnetic cores having at least one of: Fe, oriented FeSi, unoriented FeSi, FeNi, FeCo, FeSiBNbCu, FeCoMoB, FeSiB, FeSiBNb, FeSiBP, or CoZrTa,.

Example 42 may include elements of any of examples 36 through 41 where disposing a composite magnetic material at least partially about each of at least some of the one or more inductive elements may include: disposing a composite magnetic material about each of at least some of the one or more inductive elements, the composite magnetic material including magnetic particles, each of the magnetic particles including a magnetic core encapsulated in a dielectric magnetic coating that includes a soft ferrite.

Example 43 may include elements of any of examples 36 through 42 where disposing a composite magnetic material at least partially about each of at least some of the one or more inductive elements may include: disposing a composite magnetic material about each of at least some of the one or more inductive elements, the composite magnetic material including magnetic particles, each of the magnetic particles including a magnetic core encapsulated in a dielectric magnetic coating that includes at least one of: MnZn, NiZn, or Fe₂O₃.

Example 44 may include elements of any of examples 36 through 43 where disposing a composite magnetic material at least partially about each of at least some of the one or more inductive elements may include: disposing a composite magnetic material about each of at least some of the one or more inductive elements, the composite magnetic material including magnetic particles, each of the magnetic particles including a magnetic core having a diameter of from 0.05 micrometers (μm) to 500 μm.

Example 45 may include elements of any of examples 36 through 44 where disposing a composite magnetic material at least partially about each of at least some of the one or more inductive elements may include: disposing a composite magnetic material about each of at least some of the one or more inductive elements, the composite magnetic material including magnetic particles, each of the magnetic particles encapsulated in a dielectric magnetic coating having a thickness of from; 0.01 micrometer (μm) to 1 μm.

Example 46 may include elements of any of examples 36 through 45 where disposing a composite magnetic material at least partially about each of at least some of the one or more inductive elements may include: disposing a composite magnetic material about each of at least some of the one or more inductive elements, the composite magnetic material including a non-magnetic, electrically non-conductive, carrier medium that includes at least one of: a chemically, thermally, or electromagnetically curable material.

Example 47 may include elements of any of examples 36 through 46 where disposing a composite magnetic material at least partially about each of at least some of the one or more inductive elements may include: disposing a composite magnetic material about each of at least some of the one or more inductive elements, the composite magnetic material including a non-magnetic, electrically non-conductive, carrier medium that includes a thermosetting epoxy.

Example 48 may include elements of any of examples 36 through 47 where disposing one or more inductive elements in, on, or about a semiconductor substrate may include: disposing a plurality of inductive elements in, on, or about a semiconductor substrate; and where disposing a composite magnetic material at least partially about each of at least some of the one or more inductive elements may include: disposing a composite magnetic material at least partially about each of at least some of the plurality of inductive elements.

According to example 49, there is provided a system for fabricating an inductor that includes a composite magnetic material. The system may include: means for disposing one or more inductive elements in, on, or about a semiconductor substrate; means for disposing a composite magnetic material at least partially about each of at least some of the one or more inductive elements, the composite magnetic material including: a non-magnetic, electrically non-conductive, carrier medium; and a plurality of magnetic particles dispersed in the carrier medium, each of the magnetic particles including: a magnetic core; and a dielectric magnetic coating at least partially encapsulating the magnetic core.

Example 50 may include elements of example 49 where the means for disposing one or more inductive elements in, on, or about a semiconductor substrate may include: means for disposing, in, on, or about a semiconductor substrate, one or more inductive elements that include at least one of: a planar coil disposed on a single substrate layer or a stacked coil disposed across multiple substrate layers.

Example 51 may include elements of any of examples 49 or 50 where the means for disposing one or more inductive elements in, on, or about a semiconductor substrate may include: means for disposing one or more inductive elements in, on, or about a printed circuit board.

Example 52 may include elements of any of examples 49 through 51 where the means for disposing one or more inductive elements in, on, or about a semiconductor substrate may include: means for disposing one or more inductive elements in, on, or about a system-on-a-chip (SoC).

Example 53 may include elements of any of examples 49 through 52 where the means for disposing a composite magnetic material at least partially about each of at least some of the one or more inductive elements may include: means for disposing a composite magnetic material having a solids concentration of at least 40% by weight at least partially about each of at least some of the one or more inductive elements.

Example 54 may include elements of any of examples 49 through 53 where the means for disposing a composite magnetic material at least partially about each of at least some of the one or more inductive elements may include: means for disposing a composite magnetic material at least partially about each of at least some of the one or more inductive elements, the composite magnetic material including magnetic particles, each of the magnetic particles having a magnetic core that includes at least one of: Fe, oriented FeSi, unoriented FeSi, FeNi, FeCo, FeSiBNbCu, FeCoMoB, FeSiB, FeSiBNb, FeSiBP, or CoZrTa.

Example 55 may include elements of any of examples 49 through 54 where the means for disposing a composite magnetic material at least partially about each of at least some of the one or more inductive elements may include: means for disposing a composite magnetic material about each of at least some of the one or more inductive elements, the composite magnetic material including magnetic particles, each of the magnetic particles having a magnetic core encapsulated in a dielectric magnetic coating that includes a soft ferrite.

Example 56 may include elements of any of examples 49 through 55 where the means for disposing a composite magnetic material at least partially about each of at least some of the one or more inductive elements may include: means for disposing a composite magnetic material about each of at least some of the one or more inductive elements, the composite magnetic material including a plurality of magnetic particles, each of the magnetic particles encapsulated in a dielectric magnetic coating that includes at least one of: MnZn, NiZn, or Fe₂O₃.

Example 57 may include elements of any of examples 49 through 56 where the means for disposing a composite magnetic material at least partially about each of at least some of the one or more inductive elements may include: means for disposing a composite magnetic material about each of at least some of the one or more inductive elements, the composite magnetic material including a plurality of magnetic particles, each of the magnetic particles including magnetic core having a diameter of from: 0.05 micrometers (μm) to 500 μm.

Example 58 may include elements of any of examples 49 through 57 where the means for disposing a composite magnetic material at least partially about each of at least some of the one or more inductive elements may include: means for disposing a composite magnetic material about each of at least some of the one or more inductive elements, the composite magnetic material including a plurality of magnetic particles, each of the magnetic particles including a dielectric magnetic coating having a thickness of from: 0.01 micrometer (μm) to 1 μm.

Example 59 may include elements of any of examples 49 through 58 where the means for disposing a composite magnetic material at least partially about each of at least some of the one or more inductive elements may include: means for disposing a composite magnetic material about each of at least some of the one or more inductive elements, the composite magnetic material including a non-magnetic, electrically non-conductive, carrier medium that includes at least one of: a chemically, thermally, or electromagnetically curable material.

Example 60 may include elements of any of examples 49 through 59 where the means for disposing a composite magnetic material at least partially about each of at least some of the one or more inductive elements may include: means for disposing a composite magnetic material about each of at least some of the one or more inductive elements, the composite magnetic material including a non-magnetic, electrically non-conductive, carrier medium that includes a thermosetting epoxy.

Example 61 may include elements of any of examples 49 through 60 where the means for disposing one or more inductive elements in, on, or about a semiconductor substrate may include: means for disposing a plurality of inductive elements in, on, or about a semiconductor substrate; and where the means for disposing a composite magnetic material at least partially about each of at least some of the one or more inductive elements may include: means for disposing a composite magnetic material at least partially about each of at least some of the plurality of inductive elements.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

What is claimed is:

1-25. (canceled)

26. An inductor, comprising:
one or more inductive elements; and
a composite magnetic material disposed at least partially about each of at least some of the one or more inductive elements, the composite magnetic material including:
a non-magnetic, electrically non-conductive, carrier medium; and
a plurality of magnetic particles dispersed in the carrier medium, each of the magnetic particles including:
a magnetic core; and
a dielectric magnetic coating at least partially encapsulating the magnetic core.

27. The inductor of claim 26 wherein the one or more inductive elements comprise at least one of: a planar coil disposed on a single substrate layer or a stacked coil disposed across multiple substrate layers.

28. The inductor of claim 26, further comprising:
a substrate that includes at least one of:
a printed circuit board operably coupled to the one or more inductive elements; or
a system-on-a-chip (SoC) operably coupled to the one or more inductive elements.

29. The inductor of claim 26 wherein the composite magnetic material comprises a carrier having a solids concentration of at least 10% by weight.

30. The inductor of claim 26 wherein the magnetic core particles comprise at least one of: Fe, oriented FeSi, unoriented FeSi, FeNi, FeCo, FeSiBNbCu, FeCoMoB, FeSiB, FeSiBNb, FeSiBP, or CoZrTa.

31. The inductor of claim 26 wherein the dielectric magnetic coating comprises a soft ferrite.

32. The inductor of claim 31 wherein the dielectric magnetic coating comprises at least one of: MnZn, NiZn, or Fe₂O₃.

33. The inductor of claim 26:
wherein the magnetic core has a diameter of from 0.05 micrometers (μm) to 500 μm; and
wherein the dielectric magnetic coating has a thickness of from 0.01 micrometer (μm) to 1 μm.

34. The inductor of claim 26 wherein the carrier medium comprises a photocurable, chemically curable, thermally curable, or electromagnetically curable material.

35. The inductor of claim 26:
wherein the one or more inductive elements comprises a plurality of inductive elements; and
wherein the composite magnetic material encapsulates at least some of the plurality of inductive elements.

36. A method of fabricating an inductor containing a composite magnetic material, the method comprising:
disposing a composite magnetic material at least partially about each of at least some of one or more inductive elements, the composite magnetic material including:
a plurality of magnetic particles dispersed in the carrier medium, each of the magnetic particles including:
a magnetic core; and
a dielectric magnetic coating at least partially encapsulating the magnetic core.

37. The method of claim 36, further comprising:
disposing the one or more inductive elements in, on, or about a semiconductor substrate, wherein the one or more inductive elements include at least one of: a planar coil disposed on a single substrate layer or a stacked coil disposed across multiple substrate layers.

38. The method of claim 36, further comprising:
disposing the one or more inductive elements in, on, or about a substrate that includes at least one of: a printed circuit board or a system-on-a-chip (SoC).

39. The method of claim 36 wherein disposing a composite magnetic material at least partially about each of at least some of the one or more inductive elements comprises:
disposing a composite magnetic material having a solids concentration of at least 10% by weight at least partially about each of at least some of the one or more inductive elements.

40. The method of claim 36 wherein disposing a composite magnetic material at least partially about each of at least some of the one or more inductive elements comprises:
disposing a composite magnetic material at least partially about each of at least some of the one or more inductive elements, the composite magnetic material including magnetic particles that include magnetic cores having at least one of: Fe, oriented FeSi, unoriented FeSi, FeNi, FeCo, FeSiBNbCu, FeCoMoB, FeSiB, FeSiBNb, FeSiBP or CoZrTa.

41. The method of claim 36 wherein disposing a composite magnetic material at least partially about each of at least some of the one or more inductive elements comprises:
disposing a composite magnetic material about each of at least some of the one or more inductive elements, the composite magnetic material including magnetic particles, each of the magnetic particles including a magnetic core encapsulated in a dielectric magnetic coating that includes a soft ferrite.

42. The method of claim 36 wherein disposing a composite magnetic material at least partially about each of at least some of the one or more inductive elements comprises:
disposing a composite magnetic material about each of at least some of the one or more inductive elements, the composite magnetic material including magnetic particles, each of the magnetic particles including a magnetic core having a diameter of from 0.05 micrometers (μm) to 500 μm.

43. The method of claim 42 wherein disposing a composite magnetic material at least partially about each of at least some of the one or more inductive elements comprises:
disposing a composite magnetic material about each of at least some of the one or more inductive elements, the composite magnetic material including magnetic particles, each of the magnetic particles encapsulated in a dielectric magnetic coating having a thickness of from 0.01 micrometer (μm) to 1 μm.

44. The method of claim 36 wherein disposing a composite magnetic material at least partially about each of at least some of the one or more inductive elements comprises:
disposing a composite magnetic material about each of at least some of the one or more inductive elements, the composite magnetic material including a non-magnetic, electrically non-conductive, carrier medium that includes at least one of: a chemically, thermally, or electromagnetically curable material.

45. The method of claim 36 wherein disposing a composite magnetic material at least partially about each of at least some of one or more inductive elements further comprises:
disposing a composite magnetic material at least partially about each of at least some of a plurality of inductive elements.

46. A composite magnetic core material, comprising:
a non-magnetic, electrically non-conductive, carrier medium;
a plurality of magnetic particles dispersed in the carrier medium, each of the magnetic particles including:
a magnetic core; and
a dielectric magnetic coating at least partially encapsulating the magnetic core.

47. The composite magnetic core material of claim 39 wherein the composite magnetic material comprises a carrier having a solids concentration of at least 10% by weight.

48. The composite magnetic core material of claim 39 wherein the magnetic core comprises at least one of: Fe, oriented FeSi, unoriented FeSi, FeNi, FeCo, FeSiBNbCu, FeCoMoB, FeSiB, FeSiBNb, FeSiBP, or CoZrTa.

49. The composite magnetic core material of claim 14 wherein the dielectric magnetic coating comprises a soft ferrite that includes at least one of: MnZn, NiZn, or Fe₂O₃.

50. The composite magnetic core material of claim 46:
wherein the magnetic core has a diameter of from: 0.05 micrometers (μm) to 500 μm; and
wherein the dielectric magnetic coating has a thickness of from; 0.01 micrometer (μm) to 1 μm.
